(19) United States
(12) Patent Application Publication
(10) Pub. No.: US 2007/0211443 A1
(43) Pub. Date: Sep. 13, 2007

(54) System and method for postponing application of customizing components in a final drive

(75) Inventors: David Wechter, Menomonee Falls, WI (US); Richard A. Lukaszewski, New Berlin, WI (US); Sharon A. Renard, Germantown, WI (US); Jon W. Simons, Muskego, WI (US); David G. Danek, Whitefish Bay, WI (US); Michael G. Kreiter, Menomonee Falls, WI (US); Thomas A. Fuller, Waukesha, WI (US)

Correspondence Address: ROCKWELL AUTOMATION, INC./(QB), ATTENTION: SUSAN M. DONAHUE, E-7F19, 1201 SOUTH SECOND STREET, MILWAUKEE, WI, 53204, US

(73) Assignee: Rockwell Automation Technologies, Inc.

(21) Appl. No.: 11/371,838

(22) Filed: Mar. 9, 2006

(51) Int. Cl. H05K 7/00

(52) U.S. Cl. 361/782

(57) ABSTRACT

A method and product produced includes a power layer board that is manufactured by providing a printed circuit board having an input configured to receive an input power and an output configured to deliver an output power conditioned to power a motor. The method also includes soldering a first component to the printed circuit board. Thereafter, a request to manufacture the power layer board is received that includes parameters of the input power and/or the output power. Therefrom, characteristics of a second component including a resistor, a capacitor, and/or an inductor is identified based on the parameters of the input power and/or the output power. Accordingly, the identified second component is mounted to the printed circuit board through a solder-less cold-weld connector to complete the power layer board.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

The present invention relates generally to manufacturing and, more particularly, to a system and method for postponing the integration of particular components into a power layer board for a motor drive until a customer selects the characteristics of motor drive and power layer board power constraints.

Motors are a common inductive load employed at many commercial facilities. To drive a motor, an inverter including a plurality of switches is controlled to link and unlink the positive and negative (direct current) DC buses to motor supply lines. The linking-unlinking sequence causes voltage pulses on the motor supply lines that define alternating voltage waveforms of controlled magnitude and frequency. When controlled correctly, the waveforms cooperate to generate a rotating magnetic field inside a motor stator core. In an induction motor, the magnetic field induces a field in motor rotor windings. The rotor field is attracted to the rotating stator field and thus the rotor rotates within the stator core. In a permanent magnet motor, one or more magnets on the rotor are attracted to the rotating magnetic field.

The amplifier, inverter, and control circuitry are commonly referred to as a motor drive unit. Motor drives may vary according to the power required by the motor. For example, motor drives may support loads ranging from a fraction of horsepower (HP) up to thousands of HP. Similarly, drives may also vary by the type of control and markets they serve. For example, the input voltage available to a motor drive may vary depending on the country and region in which the motor drive is installed. For example, one system may be installed in the United States where the line voltage for a three-phase system is commonly 220V, 460V, 480V, or 600V, while another identical system may be installed in Europe, where the line voltage for a three-phase system may be 380V, 400V, 415V, or 690V.

Motor drives may be manufactured in different physical package sizes that support several different HP sizes. These physical packages are typically referred to as a frame. Each frame can also be adapted to support different voltage ratings. For a given frame, there may be a different power layer board (PLB) associated with each motor control board (MCB) type, the power layer board being a printed circuit suitable for handling high currents.

The PLBs may be populated with slightly different components depending on the drive requirements, often differing from other PLBs by one or two basic components such as a resistor, capacitor or inductor. Typically, PLBs meeting each of the possible combinations are built and a minimum stock level is maintained. Accordingly, the total number of bills of material (BOMs) maintained for these board configurations is large. Roughly speaking, the number of distinct BOMs may be determined by the number of frame types and horsepower ratings, and multiplied again by the number of voltage ratings, times the number of motor control board types within the family. Hence, a particular drive family may have between 100 and 200 distinct BOMs.

In order to quickly respond to customer orders, manufacturers prefabricate and maintain a stock of PLBs designed to accommodate virtually all power configurations associated with the different BOMs. When a customer orders a PLB designed to receive a given input power and provide output power to a particular motor, a PLB designed to accommodate the power parameters communicated by the customer is selected from a stock of prefabricated PLBs and installed during the motor drive assembly process. As such, the customer order is met within a relatively short turnaround time.

While this allows a manufacturer to be highly responsive to customer orders, the manufacturer must stock a large number of PCB configurations to support multiple applications. Because of market demand, some PLBs move more slowly than others. This slow turnover gives rise to problems such as delays in processing engineering change orders, obsolescence, increased inventory holding costs, consumption of resources that could have been applied to higher priority products, and additional inventory management complexity.

Ideally, the PLBs could be partially prefabricated and variations in the ultimate product accommodated by adding a few customizing components at the last moment. Unfortunately, the high current requirements of a motor drive typically dictate that the power components such as the rectifier, inverter, current sensors, line drivers, and associated scaling circuitry of the PLB be directly soldered to a single printed circuit board to provide for high current carrying capacity in the connections and connections that are resistant to mechanical shock of an industrial environment.

As is common in many manufacturing environments, soldering of these components to a printed circuit board is performed as part of a flow soldering, wave soldering or similar process in which all components are soldered essentially simultaneously (henceforth termed “mass production soldering”. However, while flow soldering is significantly more efficient and cost effective than point soldering, it requires all components to be mounted and soldered to the printed circuit board simultaneously. Flow soldering a first set of components and then hand soldering a second set of components would unduly raise the cost of manufacturing.

Accordingly, prior art manufacturing processes have been unable to provide late stage customization of power layer boards.

### BRIEF SUMMARY OF THE INVENTION

The present invention provides a power layer board (PLB) that permits mass production soldering of principle components in a “prepopulating” step and mechanical attachment of a small number of “postponed” customizing components on demand after an order is received. Key to this ability to postpone the installation of a few components is the use of solder-less, cold-weld connectors that provide suitable amperage capacity and necessary mechanical robustness.

In accordance with one aspect of the present invention, a method of manufacturing a power layer board is disclosed that includes providing a printed circuit board having an input configured to receive an input power and an output configured to deliver an output power conditioned to power a motor. The method also includes soldering a first component to the printed circuit board. Thereafter, a request to purchase the power layer board is received that includes parameters of the input power and/or the output power. Therefrom, characteristics of a second component including a resistor, a capacitor, and/or an inductor are identified based on the parameters of the input power and/or the output power. Accordingly, the identified second component is mounted to the printed circuit board through a solder-free fitting to complete the power layer board.

In accordance with another aspect of the present invention, a power layer board is disclosed that includes a printed circuit board formed from a non-conductive substrate having a plurality of conductive traces formed thereon extending from an input configured to receive an input power to an output configured to deliver an output power conditioned to power a motor. The circuit also includes a standard power-conditioning component soldered to the printed circuit board along the plurality of conductive traces to extend a path through the plurality of conductive traces from the input toward the output. A customizing power conditioning component including at least one of a resistor, a capacitor, an inductor is then mounted to the printed circuit board through a press-fitting to complete the path through the plurality of conductive traces from the input to the output.

In accordance with yet another aspect of the invention, a method of manufacturing a power layer board for a motor drive is disclosed that includes providing a printed circuit board including a plurality of conductive traces connecting an input through a plurality of through holes and press fittings to an output. The method also includes assembling a plurality of standard components in respective through holes and flow soldering the plurality of standard components in the respective through holes. Thereafter, a request to purchase the power layer board is received that includes parameters of the power layer board and a plurality of customizing components is identified based on parameters of the power layer board. The method then includes press fitting the plurality of customizing components into the printed circuit board through the press fittings to complete the power layer board according to the parameters of the power layer board requested to purchase.

Various other features of the present invention will be made apparent from the following detailed description and the drawings.

### BRIEF DESCRIPTION OF THE SEVERAL VIEWS OF THE DRAWINGS

The invention will hereafter be described with reference to the accompanying drawings, wherein like reference numerals denote like elements, and:

FIG. 1 is a simplified block diagram of an exemplary motor control system showing a power layer board constructed according to the present invention;

FIG. 2 is a flow chart setting forth the steps for manufacturing the power layer board of FIG. 1 in accordance with the present invention; and

FIG. 3 is a cross-sectional view of the power layer board of FIG. 1 showing standard flow soldered components and components mounted using a solder-less, cold weld technique.

### DETAILED DESCRIPTION OF THE INVENTION

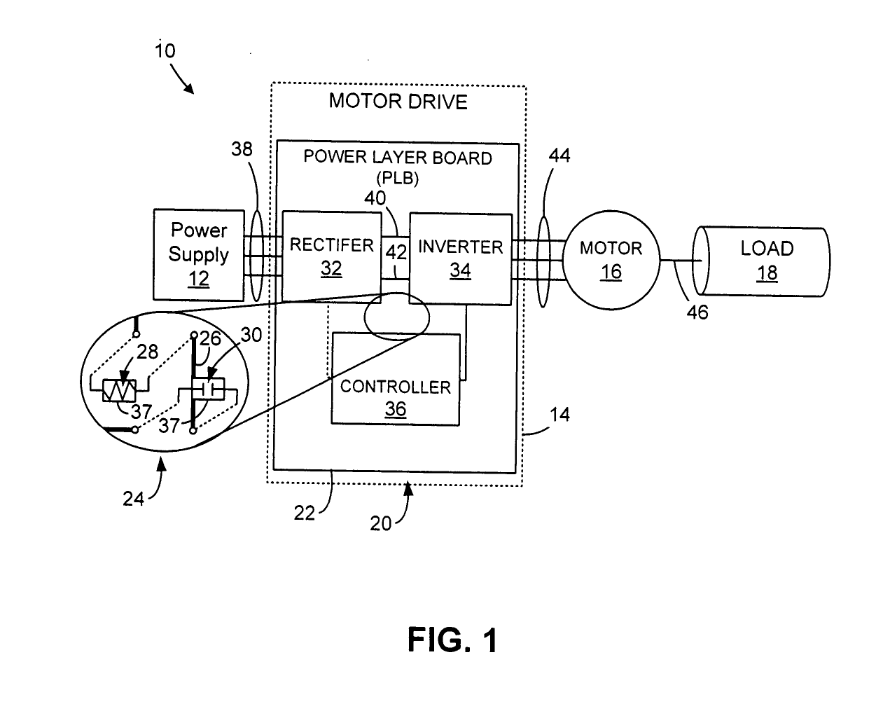

Referring now to FIG. 1, the present invention shall be described in the context of a motor control system 10. The motor control system 10 includes a power supply 12 and a motor drive 14. A three-phase motor 16, a load 18, and a plurality of lines and buses are linked by the aforementioned components together in the manner described hereinafter. The motor drive 14 includes a variety of sub-systems, of which, a power layer board (PLB) 20 is of particular importance in the context of the present invention.

The PLB 20 is constructed on a printed circuit board 22 by arranging a variety of components 24 that, as will be described, are secured by soldering or solder-free processes to the printed circuit board 22 along a plurality of conductive traces 26 that are etched on the printed circuit board 22. These components 24, for example, may include resistors 28 and capacitors 30, as well as other components such as semiconductors and the like. The components 24, when arranged along the pre-etched traces 26 form various devices that comprise the PLB 20, such as a rectifier 32, an inverter 34, and a controller 36. As will be described, the present invention advantageously allows traditional components such as resistors, capacitors, and inductors that vary based on the power constraints of the motor drive to be assembled on the printed circuit board 22 using solder-less connections, such as compliant-pin, displacement-pin, or rigid-pin connectors 37. In this regard, as will be described, carriers may be used to make these traditional components compatible with such solder-less fittings.

During operation, the power supply 12 typically provides three-phase AC power, for example, as received from a utility grid over transmission power lines 38. However, it is also contemplated that the power supply 12 may be designed to deliver single-phase power. In either case, the nominal line voltage delivered by the power supply 12 is dependent on the particulars of the motor 16, load 18, and power available to the power supply 12 to drive the motor drive 14. For example, as addressed above, the power supply 12 may be a transmission power receptacle, in which case, the power available to the motor control system 10 will be dependent upon the specifics of the geographic region in which the motor control system 10 is located (e.g. 50 Hz/60 Hz or 220 V/380V).

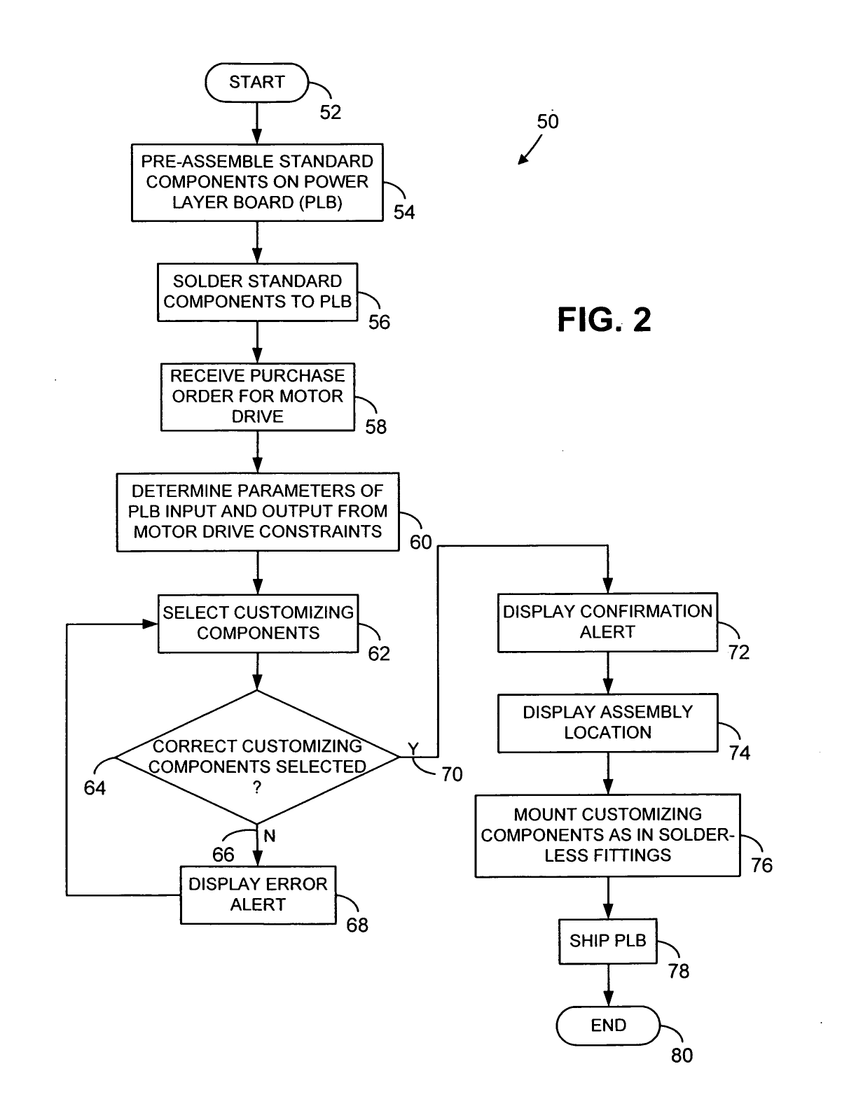

In this regard, as also described above, many of the components of the PLB 20 must be specifically selected based on the particulars of the motor 16, load 18, and power available from the power supply 12. As will be described with respect to FIG. 2, the present invention allows for these components that vary to be withheld or “postponed” from the manufacturing process until after the particulars of the motor 16, load 18, and power available to the power supply 12 are known.

The rectifier 32 is designed to receive AC power from the power supply 12 and convert the AC power to DC power. It is contemplated that various types of rectifiers may be employed to convert the AC power to DC power. For example, some rectifiers, such as a pulse width modulated (PWM) rectifier, are active and include a plurality of switching transistors. PWM rectifiers may be advantageously employed where energy present in the motor windings is regeneratively supplied back to the power supply 12 when the motor 16 is disconnected.

On the other hand, a passive rectifier, such as a multiple phase (e.g. 6, 18, or 24) diode rectifying bridge used in conjunction with a bus capacitor and filters, could be used that would not require input from the controller 36. In the case of a passive rectifier, power may be dissipated in braking resistors coupled across the motor windings when the motor 16 is disconnected.

In either case, the inverter 34 is positioned between positive and negative DC buses 40, 42 of the rectifier 32 output. As is well known in the motor control arts, the inverter 34 includes a plurality of switching devices (e.g., BJTs, etc.) that are positioned between the positive and negative DC buses 40, 42 and output supply lines 44 of the inverter 34, such that the controller 36 can open and close specific combinations of the inverter switches to generate positive and negative DC voltage pulses on each of the supply lines 44. By opening and closing the inverter switches in specific sequences, the motor drive 14 generates AC voltages having controllable amplitudes and frequencies on each of the supply lines 44.

Each of the lines 44 is linked to a separate one of three-phase windings (not separately numbered or illustrated) of the motor 16. By providing known sequences of AC voltages across the motor windings, the motor 16 is driven to turn a drive shaft 46 that, in turn, drives the load 18.

As will be described in detail with respect to FIG. 2, the present invention includes a technique for manufacturing the motor drive 14 using a postponement strategy. In particular, the technique allows the motor drive 14 and particularly, the PLB 20 of the motor drive 14, to be manufactured according to a postponement protocol where some components that do not vary across changes in motor drive ratings (referred to hereafter as “standard” components) are preassembled on the PLB 20, while other components that vary with changes in the motor drive ratings (referred to hereafter as “customizing” components) are selected and assembled on the PLB 20 at or near the final stage in the motor drive manufacturing process. That is, as referred to hereafter, standard components are components or receptacles that do not vary with PLB design requirements and, thus, will be included in the pre-populating process. On the other hand, customizing components are components that may vary with PLB design requirements and, hence, utilizing the present invention, can be postponed from assembly with a PLB 20 until after all PLB design requirements have been confirmed using a customer order.

For example, optocouplers (OC) and memory (ID EPROM) of the PLB 20 are not typically scalable and constitute standard components. However, the bus capacitor (or bank of capacitors in varying series and parallel relationships and any balancing resistors that mitigate leakage current to yield the desired capacitance), and OC are standard. On other hand, the IGBTs, the series resistors between the gate of the IGBTs and the OC, and the resistors associated with the sensing coils that perform a current to voltage conversion are all customizing components. Similarly, if a diode rectifier is utilized, the diodes forming the diode bridge are standard. Furthermore, if the power supply 12 is a three-phase supply, the protection varistors on the three-phase AC input as well as the common mode three-phase choke at the output are standard. Additionally, if included on the PLB, the DC link choke and filter capacitors are also standard.

As will be described, with the present invention, full component-level control of the manufacturing timeline is possible. That is, assembly and securing of all individual customizing components (including resistors and capacitors) on the printed circuit board can be removed from the flow soldering process and postponed within the manufacturing timeline until after the customer order is received and the characteristic of each customizing component necessary to meet the customer order is identified. Accordingly, inventory production costs as well as response time to customer orders can be reduced using the following manufacturing process.

Referring now to FIG. 2, a technique 50 for manufacturing the power layer board according to a postponement strategy starts 52 by pre-assembling the standard components and any sockets or fittings designed to receive customizing components on a PLB 54. In particular, the standard components are mounted on a printed circuit board formed from a non-conductive substrate having a plurality of conductive traces extending thereover. Similarly, any sockets, screw fittings, or other receptacles designed to receive particular customizing components are also mounted on the printed circuit board along the conductive traces. The conductive traces extend from an input configured to receive an input power from the power supply 12 of FIG. 1 to an output delivered to the motor 16 of FIG. 1. In this regard, power delivered from the output will have been conditioned to power the motor 16.

It is contemplated that each customizing component may be individually mounted to the PLB in response to the receipt of a purchase order for a motor drive without delaying the response time of the manufacturer. In this regard, it is contemplated that a solder-free mounting may be used to secure the customizing components to the PLB. For example, a compliant-pin, displacement-pin, or press-fitting system may be used to secure the customizing components to the PLB. Furthermore, screw fittings or other pre-soldered receptacles may be used to mount the customizing components solder-free on the PLB without the need for soldering processes.

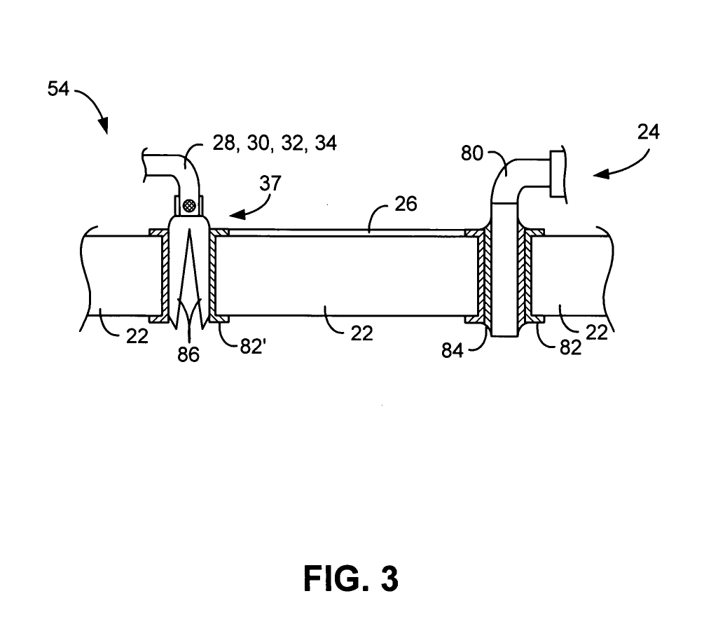

Referring to FIG. 3, a typical standard component 24 will have a lead 80 inserted into a plated-through hole 82 in the printed circuit board 22. Solder 84 will be drawn by capillary action in the flow soldering process in between the lead 80 and the inner wall of the plated-through hole 82 holding the component in place. Reheating the printed circuit board 22 after this soldering process can weaken the board and attachment of the leads 80.

In the present invention, later customizing components (28, 30, and 32) are attached to a separate plated-through hole 82′ by means of a solder-less, cold weld connector 37 such as may be commercially obtained. One version of this connector 37 comprises a fork having outwardly flexing tines 86 that deform inward as the connector 37 is press fit into the plated-through hole 82′ to cold well in a gas tight connection to the inner surface of the plated-through hole 82′. Generally, the diameter of the plated-through hole 82′ is smaller than the diagonal cross section of the connector 37 in the plane of the board 22.

The connector 37 is designed so that a plastic, as well as an elastic, deformation takes place during insertion. The two tines 86 compress to different degrees to accommodate hole tolerances and to reduce strain on the board. The residual force of the elastic deformation maintains stored energy to produce a gas-tight contact zone between the pin and the plated-through hole 82. This ensures long-term electrical and mechanical reliability of the interconnection, while eliminating the need for solder or the heat cycling of the board. While the connection is strong, the connector 37 can be removed and replaced in the same location (two repairs maximum).

In order to allow all customizing components (including capacitors and resistors rather than just large power semiconductor assemblies) to be secured using such mounting systems, it is contemplated that carriers may be utilized or the component leads may be stacked or welded directly to the connectors 37. In the former case, one or more components may be pre-assembled with a carrier that is designed to allow the resistor to be mounted through a compliant-pin, displacement-pin, or press-fitting system or even socket/receptacle system that was soldered along with the standard components.

Once preassembling of the PLB 54 is complete, the standard components are soldered to the printed circuit board 56. For example, the standard components may be soldered to the printed circuit board using flow soldering techniques common in the manufacturing industry. The partially fabricated PLB, including only the standard components as designed to receive the yet identified customizing components, can then be stored until a purchase order for a motor drive is received from a customer 58. In this regard, the parameters of the PLB input and output can be determined from the constraints of the motor drive listed with the purchase order or manufacturing order 60 and, hence, the customizing components can be identified 62.

It is contemplated that this process may be automated to increase manufacturing efficiency and accuracy. For example, the selection of the customizing components may be automatically performed by a computerized system. In this regard, a graphical illustration of the component and any identifying features may be displayed. A robot or individual may then select the component from a bin or other receptacle and confirm that the correct scalable component has been selected 64. It is contemplated that this confirmation 64 may be performed by scanning a bar code or other similar indicator that is attached to the customizing component. Alternatively, it is contemplated that some components may not include an indicator, in which case, an indicator may be mounted to the bin or receptacle containing the component.

In either case, the robot or individual scans the indicator and, if the selected component is not correct 66, an error message is displayed 68. On the other hand, if the selected component was correct 70, a confirmation alert indicating that the correct component was selected is displayed 72. Thereafter, in the case of manual assembly, a graphical illustration of the PLB may be displayed that indicates the position where the selected component should be mounted 74 on the PLB. Accordingly, an individual assembling the PLB can correctly mount the component on the PLB 76.

Therefore, the customizing components are secured to the PLB 76 in response to a customer purchase order to yield a built-to-order PLB that is then shipped to the customer 78 within a turnaround time substantially the same as required to ship a prefabricated PLB. However, using the above-described system and method, the type and amount of components required to be on hand in order to efficiently manufacture drive systems is limited while still yielding a single-board PLB that can be produced within a sufficient manufacturing turnaround.

The present invention has been described in terms of the various embodiments, and it should be appreciated that many equivalents, alternatives, variations, and modifications, aside from those expressly stated, are possible and within the scope of the invention. Therefore, the invention should not be limited to a particular described embodiment.

We claim:

1. A power layer board comprising:
a printed circuit board formed from a non-conductive substrate having a plurality of conductive traces formed thereon extending from an input configured to receive an input power to an output configured to deliver an output power conditioned to power a motor;
a plurality of standard power conditioning components soldered to the printed circuit board along at least one of the plurality of conductive traces to extend a path through the plurality of conductive traces from the input toward the output; and
at least one customizing power conditioning component selected from at least one of a resistor, a capacitor, an inductor press-fitting the printed circuit board using a solder-less, cold-weld connector to complete the path through the plurality of conductive traces from the input to the output.

2. The power layer board of claim 1 wherein the customizing power conditioning component is configured to removeably engage the printed circuit board through the press-fitting at least once.

3. The power layer board of claim 1 wherein the customizing power conditioning component includes a barcode indicating characteristics of the customizing power conditioning component.

4. The power layer board of claim 1 further comprising a plurality of additional power conditioning components mounted to the printed circuit board through the press-fitting and wherein the customizing power conditioning component and the plurality of additional power conditioning components are arranged in a common area of the printed circuit board.

5. The power layer board of claim 1 wherein the solder-less, cold-weld connector includes at least one of a compliant pin pressed into a plated-through hole in a printed circuit board.

6. A method of manufacturing a power layer board for a motor drive comprising:
providing a printed circuit board including a plurality of conductive traces connecting an input through a plurality of through holes and press fittings to an output;
assembling a plurality of standard components in respective through holes;
flow soldering the plurality of standard components in the respective through holes;
receiving a request to manufacture a power layer board including parameters of the power layer board;
identifying a plurality of customizing components based on parameters of the power layer board; and
press fitting the plurality of customizing components into the printed circuit board through solder-less, cold-weld connectors to complete the power layer board according to the parameters of the power layer board requested to purchase.

7. The method of claim 6 further comprising confirming that characteristics of each of the plurality of customizing components comply with the parameters of the power layer board included with the request to manufacture the power layer board prior to mounting the customizing components to the printed circuit board.

8. The method of claim 7 further comprising scanning a barcode associated with each of the customizing components to confirm the characteristics of each customizing component.

9. The method of claim 8 further comprising displaying a confirmation alert and a location to mount a particular customizing component on the printed circuit board in response to scanning the barcode if the characteristics of the particular customizing component complies with the parameters of the power layer board and displaying an error sign in response to scanning the barcode if the characteristics of the particular customizing component does not comply with the parameters of the power layer board.

10. The method of claim 7 wherein the plurality of customizing components includes resistors and capacitors.

11. A method of manufacturing a power layer board for a motor drive comprising:
providing a printed circuit board having an input configured to receive an input power and an output configured to deliver an output power conditioned to power a motor;
soldering a first component to the printed circuit board;
receiving a request to purchase the power layer board including parameters of at least one of the input power and the output power;
identifying characteristics of a second component including at least one of a resistor, a capacitor, and an inductor based on the parameters of at least one of the input power and the output power; and
mounting the second component to the printed circuit board, through a solder-free, cold-weld connector to complete the power layer board.

12. The method of claim 11 further comprising confirming the characteristics of the second component comply with specifications of the power layer board included with the request to purchase the power layer board prior to mounting the second component to the printed circuit board.

13. The method of claim 12 further comprising scanning a barcode associated with the second component to confirm the characteristics of the second component.

14. The method of claim 13 wherein the barcode is affixed to at least one of the second component and a storage compartment housing the second component.

15. The method of claim 13 further comprising displaying a confirmation sign in response to scanning the barcode if the characteristics of the second component are appropriate for the specifications of the power layer board and displaying an error sign in response to scanning the barcode if the characteristics of the second component are not appropriate for the specifications of the power layer board.

16. The method of claim 11 further comprising mounting the second component to the printed circuit board through a press-fitting.

17. The method of claim 16 wherein the second component is configured to removeably engage the printed circuit board through the press-fitting.

18. The method of claim 11 further comprising identifying characteristics of additional components based on the parameters of at least one of the input power and the output power, and arranging the second component and the additional components in a common area of the printed circuit board.

19. The method of claim 11 further comprising determining the parameters of at least one of the input power and the output power from specifications of the motor included with the request to purchase the power layer board.

20. The method of claim 11 further comprising a carrier engaged with the second component to facilitate mounting the second component to the printed circuit board.
